(19) United States
(12) Patent Application Publication
(10) Pub. No.: US 2026/0107717 A1
(43) Pub. Date: Apr. 16, 2026

(54) SILICON ETCH WITH DOPANT-TYPE SELECTIVITY

(71) Applicant: TOKYO OHKA KOGYO CO., LTD., Kawasaki-shi (JP)

(72) Inventors: Fusayo SAEKI, Beaverton, OR (US); Monica Janet LUNA, Hillsboro, OR (US); Kazuhiro TAKAHASHI, Hillsboro, OR (US); Akira MATSUYAMA, Hillsboro, OR (US)

(21) Appl. No.: 19/349,762

(22) Filed: Oct. 3, 2025

Related U.S. Application Data
(60) Provisional application No. 63/705,875, filed on Oct. 10, 2024.

(51) Int. Cl. H01L 21/306; C09K 13/00; H01L 21/308

(52) U.S. Cl. CPC H10P 50/642; C09K 13/00; H10P 50/691

(57) ABSTRACT

An etchant composition offers an etch rate on silicon which is sensitive to a dopant type of the silicon. The etchant composition comprises a base and an additive distinct from the base. The additive has between one and six carbon atoms per molecule.

### CROSS-REFERENCE TO RELATED APPLICATIONS

The present application claims priority to U.S. Provisional application No. 63/705,875, filed with the United States Patent and Trademark Office on Oct. 10, 2024, the entire content of which is incorporated herein by reference.

### TECHNICAL FIELD

This disclosure relates generally to the technical field of semiconductor-device fabrication and more particularly to semiconductor wet-etch processing.

### BACKGROUND

Semiconductor photolithography is a mature and sophisticated art, which is used to make integrated electronic devices of remarkable sophistication and small feature size. An elementary step in most photolithographic processing is masked etching of semiconductor or dielectric features. In masked etching, a photoresist is applied as a blanket layer over a semiconductor wafer, or die portion of the wafer, and cured via ultraviolet (UV) light projected through a carefully aligned, optical mask. Via photo-polymerization and/or photo-crosslinking, selected areas of the photoresist layer are either cured and thereby hardened in the pattern defined by the optical mask, or are degraded by the UV light. A solvent can then be used to remove the uncured or degraded portions of the photoresist, leaving behind a pattern of protected and unprotected areas.

Subsequent processing may vary from one implementation to another. In plasma etching, unprotected areas of the semiconductor wafer or die are subjected to high-energy reagents formed in a plasma. Such agents transform unprotected solid material into gaseous residues. In wet (i.e., solution-phase) etching, the unprotected areas are subjected to corrosive solutions that dissolve the undesired material; the soluble residues are subsequently washed away. In both implementations, subsequent processing typically requires removal of all portions of cured photoresist over the surface of the wafer or die. In wet-etch processing, a suitably formulated solvent composition may be used to that effect.

For example, Patent Document 1 (U.S. Pat. No. 11,180,697B2) discloses an etching solution suitable for the selective removal of polysilicon over silicon oxide from a microelectronic 55 device, which comprises: water; about 1 wt % of neat tetramethyl ammonium hydroxide (TMAH); about 15 wt % to about 20 wt % of monoethanolamine (MEA); about 50 wt % to about 59.5 wt % of ethylene glycol (EG); about 0.5 wt % of 8-hydroxyquinoline (8-HQ); and optionally, a surfactant.

### PATENT LITERATURE

Patent Document 1: U.S. Pat. No. 11,180,697 B2

### SUMMARY

One aspect of this disclosure relates to an etchant composition offering an etch rate on silicon which is sensitive to the dopant type of the silicon. The etchant composition comprises a base and an additive distinct from the base. The additive has between one and six carbon atoms per molecule.

Another aspect of this disclosure relates to a method for etching a surface having a first silicon region which is n-type and a second silicon region differing from the first with respect to dopant type. The method comprises exposing the surface to an etchant composition offering an etch rate on silicon which is sensitive to the dopant type. The etchant composition comprises a base and an additive distinct from the base, the additive having between one and six carbon atoms per molecule.

This Summary is provided to introduce in simplified form a selection of concepts that are further described in the Detailed Description. This Summary is not intended to identify key features or essential features of the claimed subject matter, nor is it intended to be used to limit the scope of the claimed subject matter. The claimed subject matter is not limited to implementations that solve any or all disadvantages noted in any part of this disclosure.

### BRIEF DESCRIPTION OF THE DRAWINGS

FIG. 1 shows aspects of an example lateral resection of an epitaxial p-type silicon (p-Si) layer.

FIG. 2 shows aspects of complete removal of an epitaxial p-type Si layer.

FIG. 3 shows the molecular structures of the chemical compounds appearing in Table 1 of this disclosure.

FIG. 4 shows aspects of an example method for etching a surface having a first silicon region which is n-type and a second silicon region differing from the first with respect to dopant type or dopant density.

### DETAILED DESCRIPTION

Wet-etch processing can provide certain advantages over plasma-etch processing for some uses in semiconductor fabrication. The operational costs may be lower, for instance, because wet-etch tools and chemicals are typically less expensive than plasma-etch tools and chemicals. In contrast to plasma-etch processing, wet-etching processing is enacted at lower temperatures, which may simplify the processing of thermally sensitive materials and structures. Wet-etch processing may also yield cleaner surfaces with less residue relative to plasma-etch processing, where residues from etchant gases and by-products may require additional cleaning protocols. In addition, wet-etching is inherently more isotropic, which can be an advantage in applications where isotropic etching is the most efficient process route to specific morphologies and/or device configurations, or for undercutting sacrificial layers.

Finally, wet-etch processing can offer greater relative etch rates (i.e., higher selectivity) for one material over another, in scenarios where a plurality of different materials are exposed concurrently to the same etch conditions. Available etchant solutions may etch silicon and silicon oxide, for example, at rates that differ by orders of magnitude. This feature provides functional selectivity for semiconductor etching versus dielectric etching. Other etchant solutions can easily discriminate between dissimilar semiconductors (e.g., germanium (Ge) versus silicon (Si)). Still other etchant solutions are available that offer a 17-fold difference in etch rate on the 100 face of silicon relative to the 111 face. Such selectivity can be exploited in order to reduce the number of mask alignments and curing steps necessary in a given fabrication process and/or enable selective removal of unprotected structures, such as undercutting.

The inventors herein have sought to extend the selectivity of wet-etch processing to semiconductor systems in which the material differences between distinct, unprotected areas of a wafer or die are extremely subtle. This includes semiconductor materials presenting the same exposed crystal face but differing only in dopant type.

Doping introduces impurities into a semiconductor. The impurities enable a space charge to develop within the doped semiconductor, which changes the Fermi level of electrons in the semiconductor relative to the valance- and conduction-band edges.

An n-type doping process adds elements with more than four valence electrons into the silicon lattice. Common n-type dopants include phosphorus (P) and arsenic (As), each with five valence electrons per atom. In effect, each n-type dopant atom adds one electron to the conduction band of silicon.

Typical dopant densities for n-type Si at low to moderate dopant levels are 10¹⁵ to 10¹⁷ atoms per cubic centimeter (cm³). For many semiconductor applications, such as integrated circuits and transistors, n-type silicon is doped in this range. Typical dopant densities for n-type Si at high dopant levels are 10¹⁸ to 10²⁰ atoms/cm³. For applications requiring high electronic conductivity, such as in certain types of power devices or specific high-speed transistors, doping concentrations in this range can be used.

A p-type doping process adds elements with fewer than four valence electrons into the silicon lattice. Common p-type dopants include boron (B), gallium (Ga), indium (In), each with three valence electrons per atom. In effect, each p-type dopant atom adds one hole to the valence band of silicon.

Typical dopant densities for p-type Si at low to moderate dopant levels are 10¹⁵ to 10¹⁷ atoms/cm³. For many semiconductor applications, such as in integrated circuits and transistors, p-type silicon is doped in this range. Typical dopant densities for p-type Si at high dopant levels are 10¹⁸ to 10²⁰ atoms/cm³. For applications requiring high hole conductivity, such as in certain types of power devices or specific high-speed transistors, doping concentrations in this range can be used.

Dopants may be added to silicon by diffusion or by ion implantation. In diffusion the wafer is exposed to a gas containing the dopant atoms at high temperatures (typically between 80° and 1200° C.). The dopants diffuse into the silicon wafer, gradually penetrating the surface and becoming incorporated into the silicon lattice. In ion implantation dopant ions are accelerated in an electric field and directed into the silicon wafer. The ions penetrate the surface and embed themselves in the silicon lattice. This method allows for more precise control of the doping concentration and depth compared to diffusion. After the doping process, the wafer typically undergoes a thermal annealing step. Thermal annealing comprises a heating process that helps to repair the damage caused by ion implantation and activates the dopants by allowing them to occupy the expected positions in the silicon lattice.

Certain portions of a semiconductor device may comprise intrinsic silicon (i-Si), in which the concentration of conduction-band electrons is equal to the concentration of valence band holes. In some examples, silicon of this type may be very pure and not subjected to any n-type or p-type dopant process (i.e., non-doped or ‘undoped’). In other examples, i-Si may be ‘intrinsically doped’, which means that n-type and p-type dopants are present in approximately equal (and typically low) concentrations, such that the Fermi level of electrons in the silicon is about the same as in non-doped silicon. The term “dopant type” as used herein includes p-type, n-type, i-type, and undoped silicon.

Amorphous silicon (a-Si) is a non-crystalline form of silicon that differs from the crystalline silicon used in most semiconductor applications. Amorphous silicon lacks a long-range periodic atomic arrangement, resulting in somewhat different electrical properties relative to crystalline silicon. For instance, amorphous silicon has a larger band gap than crystalline silicon. Amorphous silicon is usually deposited as a thin film using techniques such as CVD or PE-CVD. Amorphous silicon is often deposited in thin layers, which makes it suitable for use in flexible substrates and in various electronic devices. Generally speaking, a-Si can be doped. In the studies reported in this disclosure, however, the a-Si was intrinsic (i-Si).

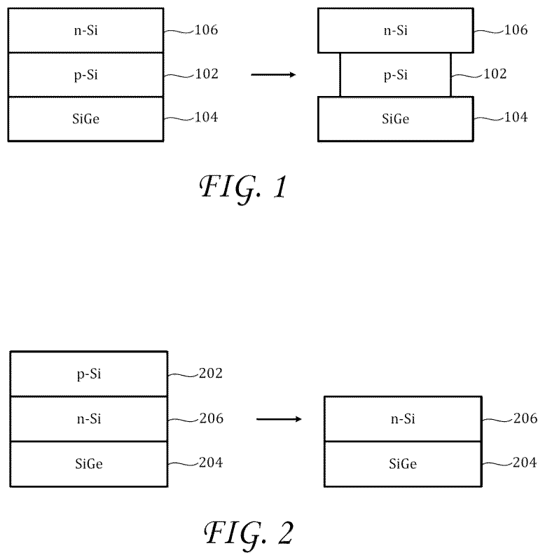

The skilled reader will appreciate that dopant densities in silicon for integrated-circuit fabrication rarely exceed 0.01% by mass. Accordingly, selective etching of p-type silicon (p-Si) in the presence of n-type silicon (n-Si), for example, is more challenging than selective etching of materials in which every etched atom is chemically distinct. Turning now to the drawings, FIGS. 1 and 2 illustrate example applications of etchant compositions and methods disclosed herein.

FIG. 1 shows aspects of an example lateral resection of an epitaxial p-Si layer 102, which is formed on an SiGe layer 104. Epitaxial n-Si layer 106, is formed on top of the epitaxial p-Si layer. The etching is achieved via wet-etch processing with p-Si and n-Si surfaces exposed concurrently to the etchant composition. As shown in the drawing, the n-Si, survives the etching with very little dimensional change, whereas the p-Si layer is significantly reduced in width.

FIG. 2 shows aspects of complete removal of an epitaxial p-Si layer 202 formed over epitaxial n-Si layer 206, which is formed on SiGe layer 204. Because the etchant composition etches p-Si much faster than it etches n-Si, layer 206 is preserved in the process.

As noted hereinabove, wet-etch processing employs certain etchant compositions for removal of material in unprotected areas of a wafer or die. The etchant compositions are chosen based upon the rate of etching target material relative to one or more collateral materials that also may be present on the surface to be etched. In this disclosure the target material is a semiconductor of a particular dopant type or dopant level. An example collateral material may be the same semiconductor of a different dopant type or of a higher or lower dopant density of the same dopant type. Other collateral materials may include the same semiconductor presenting a different crystal face (e.g., 100 versus 111), a different semiconductor (e.g., Ge versus Si), dielectrics such as silicon oxide (SiO₂) and silicon nitride (Si₃N₄), cured photoresist (which comprises one or more cross-linked polymers), and various additive structures (e.g., metal or epitaxial semiconductor features) formed on the semiconductor wafer or die surface. Such metal features may include aluminum, copper, tungsten, molybdenum, cobalt, tantalum, and gold, among others.

TABLE 1
Effect on n-Si and undoped amorphous silicon (a-Si) etch rates of amine and other
additives (each 2% by mass when included) in an etchant composition. Cx (In which
x represents an integer of 1 to 4. For example, Cx represents C1 to C4 in Table
1.) denotes a comparative etchant composition. The base was aqueous TMAH at 1%
by mass for all example and comparative etchant compositions. Note that “—”
in the table indicates that the corresponding component is not included.

| | | | n-Si etch | a-Si etch | a-Si/n-Si |
|---|---|---|---|---|---|
| etchant | | second | rate | rate | relative |
| composition | first additive | additive | (nm/min) | (nm/min) | etch rate |
| C1 | — | — | 30 | 20 | 0.7 |
| C2 | 4-dimethylaminopyridine | DEHA (2% | 40 | 25 | 0.6 |
| | (2% by mass) | by mass) | | | |
| C3 | DMHD (2% by mass) | DEHA (2% | 45 | 25 | 0.6 |
| | | by mass) | | | |
| C4 | 1,2-heptanediol (2% by | DEHA (2% | 35 | 20 | 0.6 |
| | mass) | by mass) | | | |
| 1 | DETA (2% by mass) | DEHA (2% | 30 | 120 | 4.0 |
| | | by mass) | | | |
| 2 | 1,2-ethylenediamine (2% | DEHA (2% | 35 | 110 | 3.1 |
| | by mass) | by mass) | | | |
| 3 | 1-butanol (2% by mass) | DEHA (2% | 40 | 100 | 2.5 |
| | | by mass) | | | |
| 4 | 1,3-dimethylbutylamine | DEHA (2% | 40 | 90 | 2.3 |
| | (2% by mass) | by mass) | | | |
| 5 | Triethanolamine (2% by | DEHA (2% | 40 | 130 | 3.3 |
| | mass) | by mass) | | | |
| 6 | n-butylamine (2% by | DEHA (2% | 40 | 100 | 2.5 |
| | mass) | by mass) | | | |
| 7 | DETA (2% by mass) | — | 30 | 180 | 6.0 |
| 8 | TETA (2% by mass) | — | 30 | 160 | 5.3 |
| 9 | TAEA (2% by mass) | — | 35 | 100 | 2.9 |

Table 1 shows aspects of a series of example etchant compositions 1 through 9, together with comparative etchant compositions C1 through C4. Each of the example etchant compositions and comparative etchant compositions is an aqueous solution. The amount of water in each etchant composition may exceed 90% by mass.

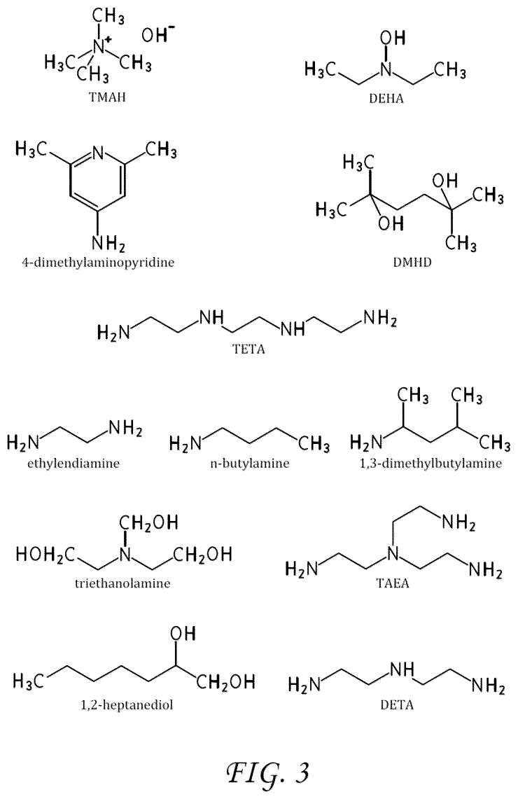

Each of the etchant compositions of Table 1 includes certain chemical compounds as solutes in the aqueous solutions. FIG. 3 shows the molecular structures of the chemical compounds used in the example and comparative etchant compositions. TMAH represents tetramethylammonium hydroxide. DEHA represents N,N-diethylhydroxylamine. DMHD represents 2,5-dimethyl-2,5-hexanediol. TETA represents triethylenetetraamine. TAEA represents tris(2-aminoethyl)amine, DETA represents diethylenetriamine.

Each of the etchant compositions of Table 1 includes a base (i.e., an alkaline component). The base is not shown in the columns of the table because the same base, TMAH at 1% by mass, was used in all of the example etchant compositions and comparative etchant compositions herein. The amount of the base is not particularly limited; base amounts in the range of 0.01% by mass to about 20% by mass are envisaged. More preferably, the amount of the base may be less than 10% by mass in some examples in order to avoid excessive corrosivity. Furthermore, in this disclosure, the lower limit of the amount of the base may be 0.1% by mass or more or 0.5% by mass or more. The upper limit of the amount of the base may be 15% by mass or less or 10% by mass or less. Bases other than TMAH may also be used. Generally speaking, the base should be freely soluble in water. Alternative bases include other quaternary ammonium bases—e.g., tetraalkylammonium hydroxides such as tetraeethylammonium hydroxide (TEAH). Sodium and potassium hydroxide may also be used, but cautiously, as such bases may introduce mobile cations into silicon during wet-etch conditions.

As one preferred example of this disclosure, each of the example etchant compositions of Table 1 includes one or more additives distinct from the base introduced above. In some examples at least one additive may comprise an amine. The term ‘amine’ should be interpreted broadly. An amine can be primary, secondary, or tertiary. Groups of atoms bonded to a nitrogen atom in an amine can be saturated, unsaturated, aliphatic, or aromatic, provided that they are stable at the pH of the etchant composition. In this disclosure ‘amine’ is a genus which embraces mono-amines, di-amines, tri-amines, and poly-amines. An amine may be mono-functional, di-functional, or poly-functional. Other functional groups compatible with the amine group and consonant with this disclosure include hydroxy groups, ether groups, and amide groups, as examples. Accordingly, the term ‘amine’ may be used to refer to a molecule having at least one amine group and one or more alcohol groups, for example. Moreover, one alcohol group may be directly bonded to an amine-nitrogen atom of an amine; the resulting hydroxylamine may still be referred to as an ‘amine’. Like the base of the example etchant compositions herein, the amine should be freely soluble in water at the pH of the etchant composition.

Example etchant compositions 1 through 9 each offer an etch rate on silicon which is sensitive to the dopant type of the silicon. The sensitivity to dopant type is revealed in the fourth, fifth, and sixth columns of Table 1. The fourth column lists the etch rate in nanometers per minute (nm/min) on n-Si, and the fifth column lists the corresponding etch rate on a film of amorphous silicon (a-Si). The sixth column shows the ratios of these rates.

The etch rates appearing in Table 1 were determined in the following manner. Epitaxial films of n-type Si were grown via chemical vapor deposition (CVD) on silicon-germanium (SiGe) wafers. Films of a-Si were grown via CVD on SiO₂-coated substrates. Each film-coated wafer was divided into a plurality of test samples of about 1 to 10 square centimeters. For each test sample, the film thickness was measured via ellipsometry or XRF.

For each test sample, 100 milliliters (mL) of aqueous hydrogen fluoride (HF, 0.5% by mass) was dispensed into a first plastic cup and stirred magnetically at 300 revolutions per minute (rpm) at 25° C. The same volume of etchant composition was dispensed into a second plastic cup and stirred magnetically at 300 rpm, at 55° C. Into third and fourth plastic cups was dispensed 100 mL of de-ionized water, stirred magnetically at 300 rpm at 25° C. Each test sample was placed in the first cup for 60 seconds, then moved to the third cup for 5 seconds, then to the second cup for 60 seconds, and then to the fourth cup for 5 seconds. The samples were then dried and the film-thickness measurement by ellipsometer or XRF was repeated.

Subjected to conventional wet-etch chemistries, n-type Si etches somewhat more rapidly than silicon of other dopant types. This is borne out in the comparative examples of Table 1. It is evident, however, that example etchant compositions 1 through 9 provide the opposite effect—lower etch rates on n-type Si than on a-Si, which is believed to be intrinsically doped silicon (i-Si). Thus, using the example etchant compositions herein, the etch rate is lower on n-type silicon than on intrinsically doped silicon, or, lower on n-type silicon than on silicon of another dopant type.

In example etchant compositions 1 through 9 of Table 1, each additive has between one and six carbon atoms per molecule. Without tying this disclosure to any particular theory, it is believed that at least one additive of the example etchant compositions enhances the etch rate on p-Si and on a-Si, and has very little effect on the etch rate on n-type Si. It is believed that additives with seven or more carbon atoms per molecule, even if freely soluble in water, may adsorb strongly to the hydrophobic surface of the silicon, which may negate the rate-enhancement effect. For instance, DETA, triethanolamine, and TETA appear to be associated with good selectivity in some compositions.

Some of the etchant compositions in Table 1 include two or more additives distinct from the base and from each other. In examples in which a plurality of additives are included, at least two of the additives may have between one and six carbon atoms per molecule, for the reasons given above. In some examples at least one of the additives may be a corrosion inhibitor, such as an N,N-disubstituted hydroxylamine; in etchant compositions 1, 2, 4, 5, and 6, the additive is DEHA. In example etchant composition 3, 1-butanol is an additive. Other branched and unbranched alcohols and polyols may also be used as additive. Some etchant compositions may include other corrosion inhibitors besides the specified additive; that feature is not necessary, however.

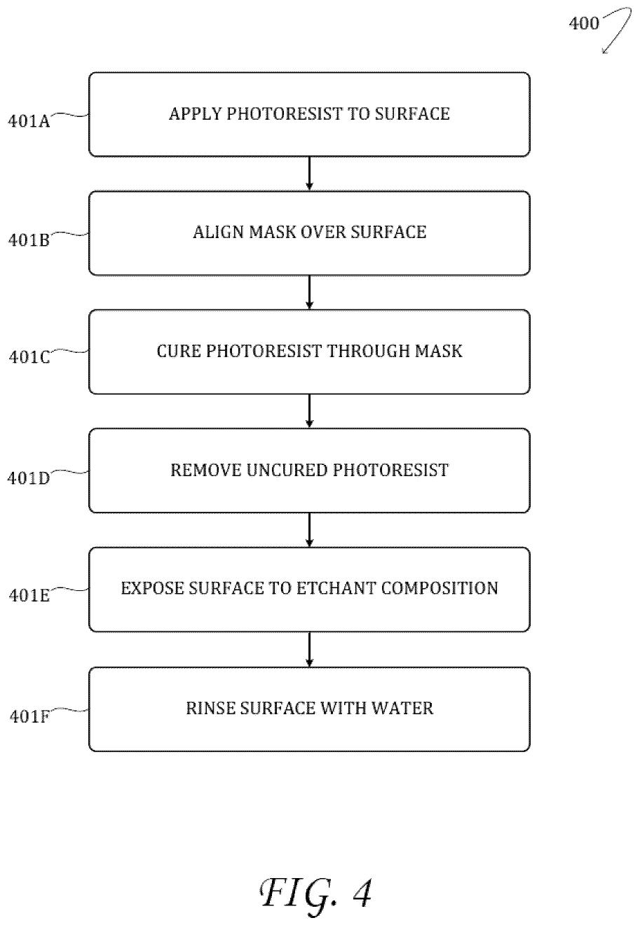

FIG. 4 shows aspects of an example method 400 for etching a surface having a first silicon region which is n-type and a second silicon region differing from the first with respect to dopant type or dopant density.

At 401A of method 400 a photoresist is applied to the surface. At 401B a mask is aligned over the surface. At 401C the photoresist is cured by UV exposure through the mask, such that no cured photoresist extends over the first silicon region or the second silicon region. At 401D the uncured photoresist is removed from the surface.

At 401E the surface is exposed to an etchant composition offering an etch rate on silicon which is sensitive to the dopant type. The etchant composition comprises a base and an additive distinct from the base. As illustrated by the example etchant compositions herein, the additive may have between one and six carbon atoms per molecule. In some examples the etch rate of the composition is lower on the first, n-type silicon than on silicon of another dopant type, such as the second region. Such other dopant types may include one or more of p-type, intrinsically doped, amorphous, and/or non-doped.

In some examples the base comprises a quaternary ammonium base, such as TMAH or TEAH. In some examples the additive comprises an amine. In some examples the etchant solution may comprise two or more additives distinct from the base and from each other. In some examples at least two additives may have between one and six carbon atoms per molecule. In some examples the amine or other additive may comprise an N,N-disubstituted hydroxylamine, such as DEHA.

At 401F the surface is rinsed. In some examples the rinsing agent may comprise water. In some examples the rinsing agent may comprise an alcohol, such as isopropyl alcohol. Optionally, after the surface is rinsed and suitably dried, one or more dry-etch processes may be enacted, as desired.

No aspect of this disclosure should be interpreted in a limiting sense, for numerous variations, extensions, and omissions are equally envisaged. For instance, while the method of FIG. 4 illustrates selective etching after circuit patterning, selective etching according to the methods herein may also be useful before patterning or in between separate patterning procedures. Although the foregoing description refers specifically to etchant compositions with selectivity based on dopant type, the same or similar etchant compositions may show etch-rate selectivity based on dopant density—e.g., normal dopant density versus high dopant density versus degenerate doping. Moreover, the same or similar etchant compositions may show etch-rate sensitivity based on dopant depth—e.g., deep doping versus shallow doping.

Again, while no aspect of this disclosure is tied to any particular theory, it may be the case that the primary chemical effect of the dopant type and dopant density is to influence the space charge that develops within the semiconductor material when the semiconductor surface comes to electrostatic equilibrium with the etchant composition. Such equilibrium causes charge to accumulate, in dependence on the dopant type, dopant density, and dopant depth, at the interface between the semiconductor surface and the solution. It is plausible that the relative etch rates reported in this disclosure as a function of dopant type are due to the changes in surface chemistry that result from the accumulated surface charge and are therefore extensible to dopant depth and to dopant density.

This disclosure is presented by way of example and with reference to the attached drawing figures. Components, process steps, and other elements that may be substantially the same in one or more of the figures are identified coordinately and described with minimal repetition. It will be noted, however, that elements identified coordinately may also differ to some degree. It will be further noted that the figures are schematic and generally not drawn to scale. Rather, the various drawing scales, aspect ratios, and numbers of components shown in the figures may be purposely distorted to make certain features or relationships easier to see.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed. In some examples the terms ‘about’ and ‘approximately’, as applied to a numeric value x, expand x to include any value in a range between 0.9x and 1.1x; in some examples these terms expand x to include any value in a range between 0.95x and 1.05x.

In addition, the configurations and parameters disclosed in the present specification can be any combination unless otherwise specified. Furthermore, an upper limit and a lower limit of the values disclosed in the present specification can be any combination unless otherwise specified. As used herein, the term “comprise” can be optionally substituted with “consist essentially of” or “consist of”. Furthermore, throughout the specification, unless the context requires otherwise, “parts” and “%” refer to “parts by mass” and “% by mass”, respectively. The amount of each component used (blending amount) may be interpreted as the content thereof in a composition, and vice versa.

The subject matter of the present disclosure includes all novel and non-obvious combinations and sub-combinations of the various processes, systems and configurations, and other features, functions, acts, and/or properties disclosed herein, as well as any and all equivalents thereof.

This disclosure also includes embodiments exemplified below.
<1> An etchant composition offering an etch rate on silicon which is sensitive to a dopant type of the silicon, the etchant composition comprising:
   a base; and
   an additive distinct from the base, the additive having between one and six carbon atoms per molecule.
<2> The etchant composition of <1> wherein the etch rate is lower on n-type silicon than on intrinsically doped silicon, or, lower on n-type silicon than on silicon of another dopant type.
<3> The etchant composition of <1> wherein the base comprises a quaternary ammonium base.
<4> The etchant composition of <1>, wherein the additive comprises an amine.
<5> The etchant composition of <1>, wherein the additive is a first additive, the etchant composition further comprising a second additive distinct from the base and from the first additive.
<6> The etchant composition of <5> wherein the second additive has between one and six carbon atoms per molecule.
<7> The etchant composition of <5>, wherein the second additive comprises an amine or an alcohol.
<8> A method for etching a surface having a first silicon region which is n-type and a second silicon region differing from the first with respect to dopant type, the method comprising:
   exposing the surface to an etchant composition offering an etch rate on silicon which is sensitive to the dopant type, the etchant composition comprising a base and an additive distinct from the base, the additive having between one and six carbon atoms per molecule.
<9> The method of <8> wherein the etch rate is lower on the n-type silicon than on silicon of another dopant type.
<10> The method of <8> further comprising:
   applying a photoresist to the surface;
   aligning a mask over the surface;
   curing the photoresist through the mask, such that no cured photoresist extends over the first silicon region or the second silicon region; and
   removing the photoresist left uncured.
<11> The method of <8> further comprising rinsing the surface and/or enacting a dry-etch process.
<12> The method of <8> wherein the base comprises a quaternary ammonium base.
<13> The method of <8> wherein the additive comprises an amine.
<14> The method of <8>, wherein the additive is a first additive, and wherein the etchant solution further comprises a second additive distinct from the base and from the first additive.
<15> The method of <14> wherein the second additive has between one and six carbon atoms per molecule.
<16> The method of <14> wherein the first additive is an amine or an alcohol.
<17> An etchant composition offering an etch rate on silicon which is sensitive to a dopant type of the silicon, the etchant composition comprising:
   a base;
   a first additive distinct from the base, the first additive having between one and six carbon atoms per molecule; and
   a second additive distinct from the base and from the first additive, the second additive having between one and six carbon atoms per molecule.
<18> The etchant composition of <17> wherein the base comprises a quaternary ammonium base.
<19> The etchant composition of <17> wherein the first additive comprises an amine.
<20> The etchant composition of <17> wherein the first additive comprises an amine or an alcohol, and the second additive comprises an amine or an alcohol.

1. An etchant composition offering an etch rate on silicon which is sensitive to a dopant type of the silicon, the etchant composition comprising:
a base; and
an additive distinct from the base, the additive having between one and six carbon atoms per molecule.

2. The etchant composition of claim 1 wherein the etch rate is lower on n-type silicon than on intrinsically doped silicon, or, lower on n-type silicon than on silicon of another dopant type.

3. The etchant composition of claim 1 wherein the base comprises a quaternary ammonium base.

4. The etchant composition of claim 1, wherein the additive comprises an amine.

5. The etchant composition of claim 1, wherein the additive is a first additive, the etchant composition further comprising a second additive distinct from the base and from the first additive.

6. The etchant composition of claim 5 wherein the second additive has between one and six carbon atoms per molecule.

7. The etchant composition of claim 5, wherein the second additive comprises an amine or an alcohol.

8. A method for etching a surface having a first silicon region which is n-type and a second silicon region differing from the first with respect to dopant type, the method comprising:
exposing the surface to an etchant composition offering an etch rate on silicon which is sensitive to the dopant type, the etchant composition comprising a base and an additive distinct from the base, the additive having between one and six carbon atoms per molecule.

9. The method of claim 8 wherein the etch rate is lower on the n-type silicon than on silicon of another dopant type.

10. The method of claim 8 further comprising:
applying a photoresist to the surface;
aligning a mask over the surface;
curing the photoresist through the mask, such that no cured photoresist extends over the first silicon region or the second silicon region; and
removing the photoresist left uncured.

11. The method of claim 8 further comprising rinsing the surface and/or enacting a dry-etch process.

12. The method of claim 8 wherein the base comprises a quaternary ammonium base.

13. The method of claim 8 wherein the additive comprises an amine.

14. The method of claim 8, wherein the additive is a first additive, and wherein the etchant solution further comprises a second additive distinct from the base and from the first additive.

15. The method of claim 14 wherein the second additive has between one and six carbon atoms per molecule.

16. The method of claim 14 wherein the first additive is an amine or an alcohol.

17. An etchant composition offering an etch rate on silicon which is sensitive to a dopant type of the silicon, the etchant composition comprising:
a base;
a first additive distinct from the base, the first additive having between one and six carbon atoms per molecule; and
a second additive distinct from the base and from the first additive, the second additive having between one and six carbon atoms per molecule.

18. The etchant composition of claim 17 wherein the base comprises a quaternary ammonium base.

19. The etchant composition of claim 17 wherein the first additive comprises an amine.

20. The etchant composition of claim 17 wherein the first additive comprises an amine or an alcohol, and the second additive comprises an amine or an alcohol.
